(19) United States
(12) Patent Application Publication
(10) Pub. No.: US 2003/0209805 A1
(43) Pub. Date: Nov. 13, 2003

(54) Flourine doped SiO2 film and method of fabrication

(76) Inventors: Chi-Hing Choi, Portland, OR (US); John Bumgarner, Tempe, AZ (US); Todd Wilke, West Vancouver (CA); Melton Bost, Hillsboro, OR (US)

Correspondence Address: Michael A. Bernadicou, Esq., BLAKELY, SOKOLOFF, TAYLOR & ZAFMAN LLP, 12400 Wilshire Boulevard, Seventh Floor, Los Angeles, CA, 90025-1026, US

(21) Appl. No.: 10/396,659

(22) Filed: Mar. 24, 2003

Related U.S. Application Data
(62) Division of application No. 09/451,464, filed on Nov. 30, 1999.

(51) Int. Cl. H01L 21/50; H01L 23/48; H01L 29/40

(52) U.S. Cl. 257/758; 257/645; 257/646; 257/651; 438/118; 438/622; 257/776; 438/280

(57) ABSTRACT

The present invention is a dielectric film and its method of fabrication. The dielectric film of the present invention includes silicon oxygen fluorine and nitrogen wherein the interlayer dielectric comprises between 0.01-0.1 atomic percent nitrogen.

### BACKGROUND OF THE INVENTION

1. Field of the Invention

The present invention relates to the field of semiconductor integrated circuit manufacturing and more specifically to a flourine doped nitrogen containing silicon oxide dielectric film.

2. Discussion of Related Art

As device feature size continues to shrink in order to fabricate higher and higher density integrated circuits, the on chip resistance and capacitance (RC) time delay and cross talk between metal lines has become a major limitation in achieving high speed circuits. One method of reducing the RC delay and cross talk is to use low dielectric constant intermetal dielectrics. Flourine doped silicon dioxide (SiO₂) has been proposed as an intermetal dielectric because of its low dielectric constant and its ease of intregration into current interconnection processing.

A current method of forming a flourine doped SiO₂ layer in order to meet gap fill requirements for sub micron processes is by high density plasma (HDP). In such a processes a silicon-flourine gas, O₂ and argon are fed into a plasma chamber. Argon is added into the high density plasma in order to achieve high sputtering density and good gap fill. Unfortunately, however, the use of argon as a sputtering gas has been found to make the flourine doped SiO₂ film unstable and to exhibit poor adhesion properties. It has been found that argon and unstable flourine species can become trapped in interstitial sites and thereby cause film adhesion problems as the argon and flourine species desorbs from the flourine doped SiO₂ film at elevated temperatures.

### SUMMARY OF THE INVENTION

The present invention is a dielectric film which includes silicon, oxygen, fluorine and nitrogen wherein the dielectric film comprises between 0.01-0.1 atomic percent nitrogen.

### BRIEF DESCRIPTION OF THE DRAWINGS

FIG. 1 is an illustration of a cross-sectional view of a semiconductor substrate including a flourine doped nitrogen containing silicon oxide film.

FIG. 2 is an illustration of an overhead view of a high density plasma reactor which can be used to deposit the flourine doped nitrogen containing silicon oxide film of the present invention.

FIG. 3 is an illustration of a cross-sectional view showing the formation of a flourine doped nitrogen containing silicon-oxide film of the present invention over the substrate of FIG. 1.

FIG. 4 is an illustration of a cross-sectional view showing the planarization and formation of via openings in the substrate of FIG. 3.

FIG. 5 is an illustration of a cross-sectional view showing the filling of the via openings in the substrate of FIG. 4 with a conductive material.

FIG. 6 is an illustration of a cross-sectional view showing the formation of a second level of metalization on the substrate of FIG. 5.

### DETAILED DESCRIPTION OF THE PRESENT INVENTION

The present invention is a low dielectric constant film and its method of fabrication. In the following description numerous specific details are set forth in order to provide a thorough understanding of the present invention. It is to be appreciated that these specific details are only illustrative of an embodiment of the present invention and are not necessarily to be taken as limiting. Additionally, in other instances well known semiconductor fabrication processes and materials have not been set forth in particular detail in order to not obscure the present invention.

The present invention is a low dielectric constant flourine doped nitrogen containing silicon oxide dielectric and its method of fabrication. The dielectric of the present invention is ideally suited for use as an intrametal dielectric in the fabrication of semiconductor integrated circuits. The dielectric film of the present invention consists of silicon, oxygen, flourine, and nitrogen. The dielectric film comprises approximately 33 atomic percent silicon, between 0.01-0.1 atomic percent nitrogen, between 3-10 atomic percent fluorine and the remainder oxygen. The dielectric film of the present invention exhibits a dielectric constant of less than 4.0 and typically in the range of between 3.2 to 3.7. The dielectric film can be formed by a high-density plasma (HDP) process utilizing a process gas mixture comprising a silicon fluorine compound, such as SiF₄, an oxygen containing gas, such as O₂ and a nitrogen containing gas, such as N₂. Utilizing a nitrogen containing gas such as nitrogen N₂ as the sputtering gas in an HDP process incorporates nitrogen into the fluorine doped silicon oxide film which thereby improves the films stability by minimizing its moisture absorption. Additionally the film exhibits good adhesion to metal surfaces due to the interaction between the metal and nitrogen incorporated into the film. Additionally, since the film can be formed by a high density plasma process it can fill high aspects ratio gaps or openings.

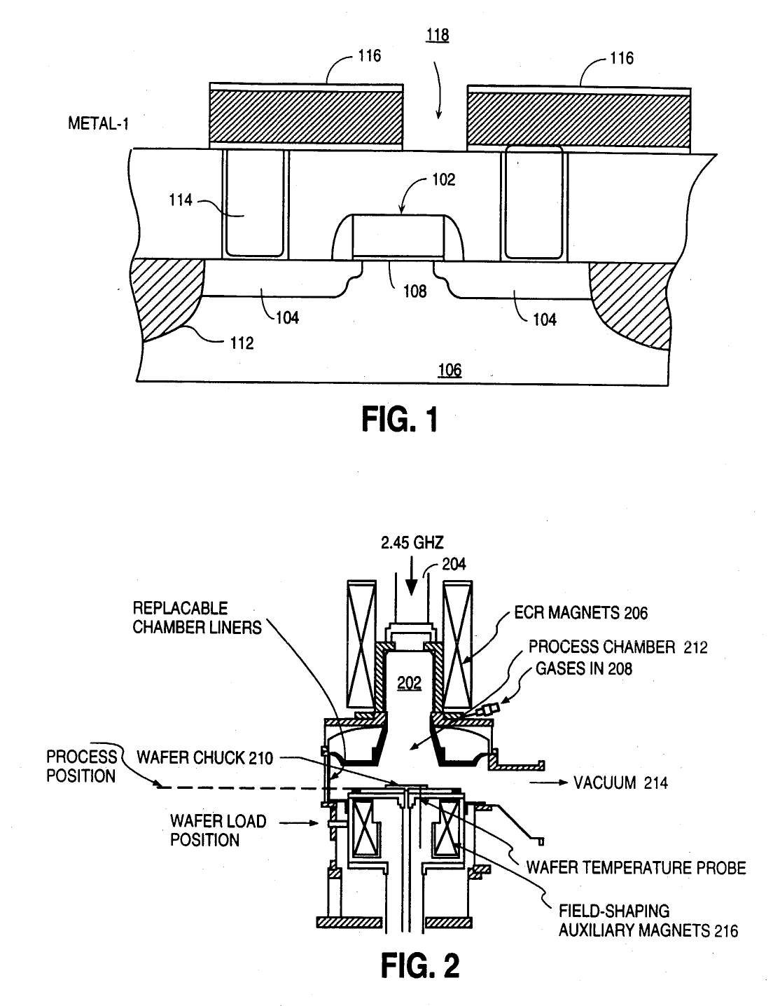

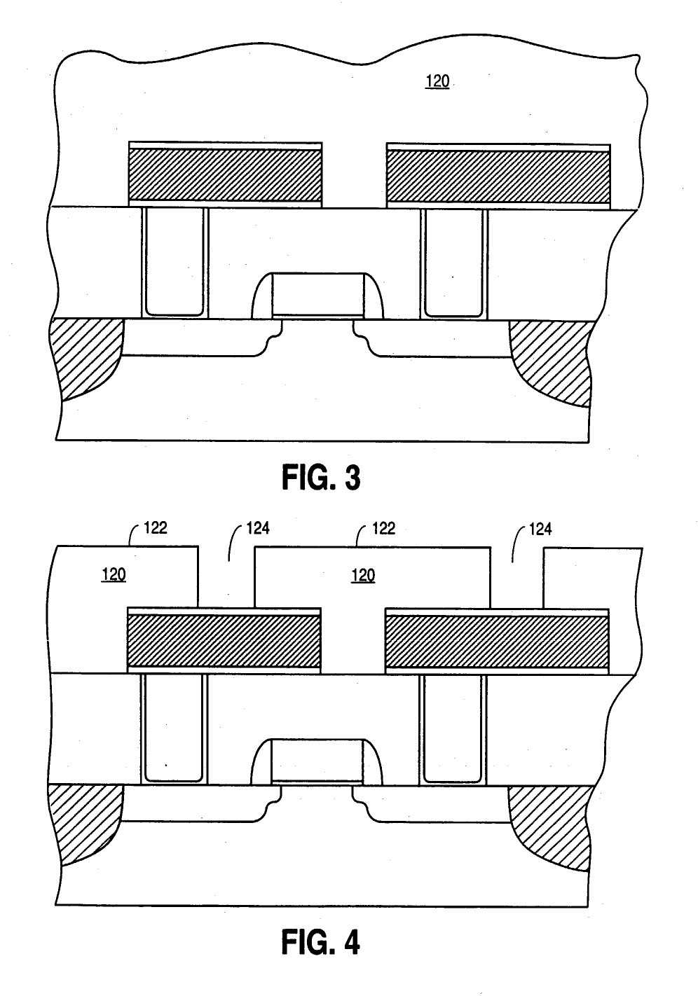

The flourine doped nitrogen containing silicon dioxide film of the present invention is ideally suited for use as an intermetal dielectric in the fabrication of semiconductor integrated circuits. In the process of fabricating an intermetal dielectric for a semiconductor device, a substrate, such as substrate 100 shown in FIG. 1, is provided. Substrate 100 is a partially fabricated integrated circuit which includes a plurality of active devices 102, such as metal oxide semiconductor (MOS) transistors. An MOS device 102 includes a pair of source/drain regions 104 formed in a monocrystalline silicon substrate 106 as well as a gate insulating layer 108 formed on the silicon substrate 106 and a gate electrode 110 formed on the gate dielectric 108. Field isolation regions 112 are formed in the silicon substrate 106 to isolated adjacent MOS transistors. Metal contacts 114, such as tungsten contacts which may or may not include barrier metals, provide electrical connection through dielectric 113 between metal lines 116 in a first level of metalization and the underlying MOS device.

The present invention is described with respect to the formation of an intermetal dielectric onto the substrate 100 in order to isolate the metal interconnect lines 116 of the first level of metalization (e.g. metal 1) from a second level of metalization (metal 2). It is to be appreciated that the present invention is equally applicable to the isolation of alternate levels of metalization such as between metal 2 and metal 3 and metal 3 and metal 4 etc. Because the intermetal dielectric of the present invention has good gap fill characteristics the present invention can be used to form a dielectric between small gaps 118 between metal lines 102. In this way the metal lines or features can be separated by the minimum design rules enabling the fabrication of high density integrated circuits. The low K dielectric film of the present invention can be used to fill gaps having a width of less than 0.25 μm and an aspect ratio as great as 3:1. (Aspect ratio=height:width).

It is to be appreciated that the process of the present invention can be used to deposit a dielectric film on other types of semiconductor substrates such as those used in the fabrication of memory devices such as DRAMs and EEPROMs or other types of logic devices such as FPGA's and ASCIC's and can be used on other types of substrates such as those used for flat panel displays. In short the process of the present invention can be used in any place a low dielectric constant high quality dielectric film is required.

In an embodiment of the present invention the low dielectric constant fluorine doped nitrogen containing silicon oxide film of the present invention is formed in a high density plasma (HDP) reactor. An example of such a reactor is the LAM Research Corporation EPIC ECR plasma CVD reactor illustrated in FIG. 2. An example of another suitable HDP reactor is the LAM DSM9900 reactor. The high density plasma reactor 200 shown in FIG. 2 includes a plasma generation chamber 202 which receives microwaves (2.45 GHz) from a microwave generator source 204. The plasma chamber 202 is surrounded by ECR magnets 206. A process gas mix including a silicon-flourine compound, such as SiF₄, an oxygen containing gas, such as O₂, and a nitrogen containing gas, such as N₂ are provided by a gas inlet 208 into the plasma chamber 202 where they are exposed to microwaves to generate a plasma. High density plasma reactor 200 includes a wafer chuck 210 located in a process chamber area 212. The wafer or substrate is heated by energetic ion bombardment (plasma heating). The temperature of the chuck and substrate are controlled by backside helium cooling. A vacuum source 214, such as a turbo molecular pump, is connected to the process chamber 212 so that the pressure in the chamber can be reduced below atmospheric pressure, such as between 1.0-10 mtorr, during deposition. The wafer chuck 210 can receive an RF bias to enable ion imbombardment which produces better etching which enables the ability to fill high aspect ratio openings without voids therein. Additionally, auxiliary shaping magnets 216 can be located beneath the wafer chuck 210 in order to help extract and direct ions to the surface of the wafer.

In order to deposit a flourine doped nitrogen containing silicon dioxide film in HDP reactor 200, in accordance with the present invention, a substrate, such as substrate 100 shown in FIG. 1, is placed onto chuck 210 face up in process chamber 216. The total pressure in chamber 212 is then reduced to between 1.0-10 mtorr and preferably between 1.0-5 mtorr and ideally to 2 mtorr. While maintaining the deposition pressure a process gas mix comprising a silicon-flourine compound, and oxygen containing gas, and a nitrogen containing gas are fed into the plasma chamber. In a preferred embodiment of the present invention the silicon flourine compound is silicon tetraflouride (SiF₄), however, other silicon flourine precursors such as SiH₂F₂ can be used. In a preferred embodiment of the present invention the oxygen containing gas is O₂, however, other oxygen containing gases such as N₂O can be utilized. In a preferred embodiment the nitrogen containing gas is N₂, however, other nitrogen containing gases such as N₂O can be used.

The process gas mix is exposed to microwaves in plasma chamber 202 where the oxygen containing gas disassociates to provide oxygen radicals, the silicon-flourine compound disassociates to provide silicon-flourine radicals, and the nitrogen containing gas disassociates to provide nitrogen radicals. A microwave power of between 1500-2000 watts can be used to disassociate the process gas. The silicon flourine radicals and oxygen radicals then combine to form a silicon dioxide film (SiO₂) doped with flourine. Additionally, because nitrogen (N₂) is included into the process gas mix nitrogen radicals are formed, and incorporated into the film. The energetic ion bombardment of the substrate by the radicals heats the substrate. The substrate temperature is maintained by backside cooling at between 300-450° C. and preferably at about 400° C. during deposition. The process gas mix is continually fed into the deposition chamber and the total pressure and temperature maintained until a silicon dioxide film doped with flourine and incorporating nitrogen is deposited to its desired thickness.

The flow rates and partial pressures of a silicon-flourine compound, the oxygen containing gas, and the nitrogen containing gas are chosen to produce a dielectric film 120 having a desired composition of silicon, oxygen, flourine and nitrogen. In an embodiment of the present invention the dielectric film is a silicon oxide film having approximately 33 atomic percent silicon, between 3-10 atomic percent flourine, and between 0.01-0.01 atomic percent nitrogen and the remainder oxygen. Such a film can exhibit an extremely low dielectric constant of between 3.2-3.7. It is to be appreciated that larger amounts of nitrogen can be included in the film if desired, however, increasing the amount of nitrogen increases the amount of silicon nitride incorporated into the interlayer dielectric which increases the dielectric constant of the film. It is to be appreciated that it is desirable to form a silicon oxide interlayer dielectric having a dielectric constant less than silicon dioxide (4.0). Additionally, it is to be noted that the process of the present invention produces a dielectric film which is essentially a silicon dioxide film except that a various oxygen cites in the crystal lattice nitrogen or flourine replaces oxygen atoms. Additionally, some N₂ can be incorporated into intersititial cites within the lattice.

In order to produce a film having between 3-10 atomic percent flourine and between 0.01-0.1 atomic percent nitrogen, silicon tetraflourine (SiF₄) can be fed into reactor 200 at a rate of between 10-100 sccm and preferably at a rate of 50 sccm to produce a silicon-flourine compound partial pressure of between 0.1-1.0 mtorr, and O₂ can be fed into plasma chamber 202 at a rate of between 100-200 sccm to produce an O₂ partial pressure of between 1-2 mtorrs and N₂ can be fed into plasma chamber 202 at a rate of between 10-30 sccm to produce an N₂ partial pressure between 0.1-0.2 mtorr with the total pressure is maintained between 1.0-10 mtorr and preferably between 1-5 mtorr and ideally at about 2 mtorr. In an embodiment of the present invention the oxygen containing gas, the partial pressure to nitrogen containing gas partial pressure is at least 5:1.

In an embodiment of the present invention the oxygen containing gas nitrogen containing gas and argon or combinations thereof, are first fed into the plasma chamber (without a silicon flourine compound or silicon source gas) in order to heat the substrate to a desired deposition temperature prior to any deposition. Once the deposition temperature is reached, a process gas mix comprising a silicon flourine compound, an oxygen containing gas, and a nitrogen containing gas are fed into the plasma chamber and deposition begun. It is to be noted that if desired argon can be included into the process gas mix during deposition. Additionally, in an embodiment of the present invention the silicon flourine compound component of the process gas mix can be made up of a silicon flourine compound and a silicon source gas such as but not limited to SiH₄ and disilane Si₂H₆.

The flourine doped nitrogen containing silicon oxide film 120 of the present invention is deposited until a sufficiently thick film is formed which can isolate a subsequent level of metalization (e.g. metal 2) from the first level metalization. In an embodiment of the present invention the dielectric layer 120 is deposited to a thickness between approximately 1.0-3.0 microns.

After deposition, the dielectric layer 120 can be planarized, as shown in FIG. 4, by any well known technique such as by chemical mechanical planarization or by plasma etch back to form a planar top surface 122. Via openings 124 can then be formed in dielectric layer 120 by well known photolithographic and etching techniques. The flourine doped nitrogen containing silicon oxide film of the present invention can be anisotropically etched with any well known silicon dioxide etchant and etching technique such as plasma etching with C₂F₈. Additionally, the film 120 can be wet etched with HF.

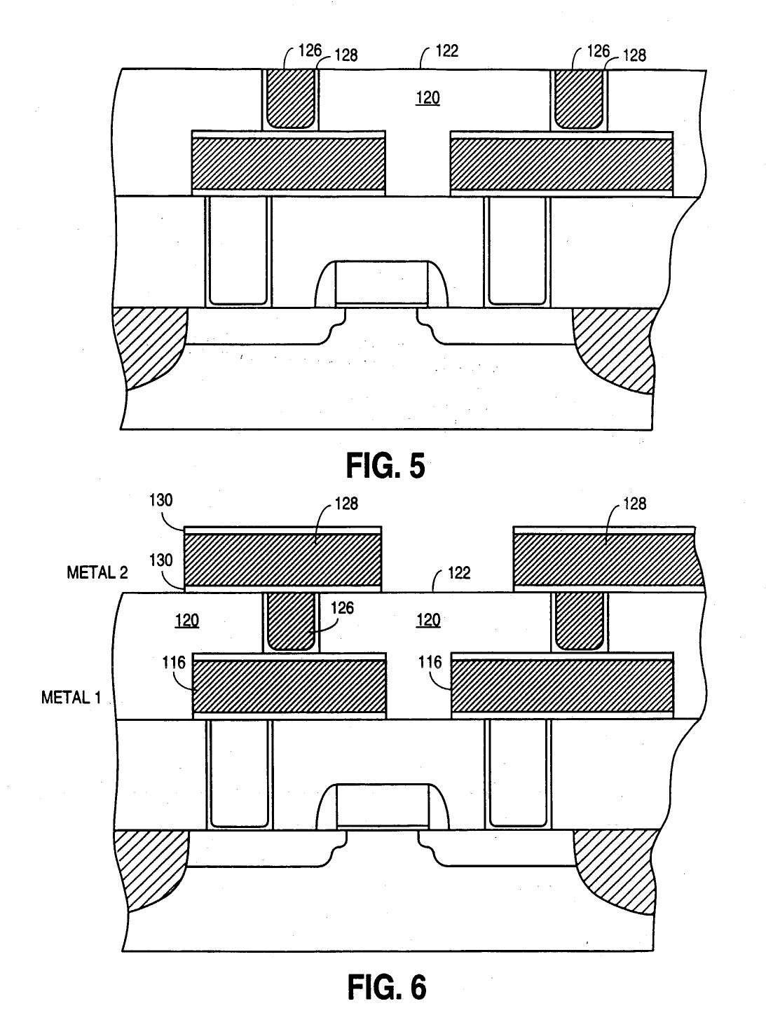

As shown in FIG. 5 the via openings 126 are filled with a metal conductor, such as tungsten, to form conductive vias 126. Conductive vias 126 can be formed by blanket depositing a conductive film, such as tungsten, over ILD 122 and into via openings 124. The conductive film can then be removed from the planar top surface 122 of ILD 120 by for example chemical mechanical planarization or by plasma etching to form conductive vias 126. It is to be appreciated that other techniques such as electroplating and other metals such as but not limited to and aluminum or copper can be used to form conductive vias 126. Additionally, conductive 126 may or may not include barrier layers 128.

Next, second level of metal interconnects 128 (e.g. metal 2) is formed over ILD 122 and in contact with conductive vias 126 as shown in FIG. 6. Interconnects 129 can be formed by blanket depositing, by for example sputter deposition, a metal conductor such as aluminum and its desired barrier metals over ILD 122. The blanket deposited metal conductors can then be patterned into interconnects lines 128 by well known photolithographic and etching techniques. It is to be noted that because nitrogen is incorporated into ILD 120, the adhesion of the metal lines 128 to the ILD 120 is improved.

Although one technique for forming via as interconnects in an on ILD 120 has been described, other well known techniques such as damascene and dual damascene can be used if desired. The above described flourine doped nitrogen containing silicon oxide film formation process and via/interconnect formation process can be continued to provide additional levels of metalization and isolation as desired.

A method for forming a low dielectric constant silicon dioxide dielectric which is doped with flourine of which contains nitrogen has been described. The dielectric film exhibits a low dielectric constant (less than 4.0) which thereby reduces the on chip resistance-capacitance (RC) time delay and the capacitive coupling (cross talk) between adjacent metal lines (e.g. lines 116) and between levels of metalization (e.g., metal 1 and metal 2). The dielectric film 120 can be deposited into high aspect ratio opening (aspect ratios as high as 3.5:1). Additionally, because the film includes a small amount of nitrogen, the film exhibits excellent moisture resistance and therefore film quality and characteristic stability. It is to be noted that although the flourine doped nitrogen containing silicon oxide film of the present invention is ideally suited as a stand alone ILD to separate various levels of metalization, ILD 120 can be used to form a portion, such as the top or bottom portion of an ILD if desired. The present invention can be used anywhere a low dielectric constant (less than 4.0) high quality moisture resistant dielectric is desired.

We claim:

1. An interlayer dielectric, said interlayer dielectric comprising:
silicon-oxygen-fluorine-and nitrogen wherein said interlayer dielectric comprises between 0.01-0.1 atomic percent nitrogen.

2. The interlayer dielectric of claim 1 wherein said interlayer dielectric comprises between 3-10 atomic percent fluorine.

3. An integrated circuit, said integrated circuit comprising:
a substrate;
a patterned metal layer formed above said substrate; and
an interlayer dielectric formed over said patterned metal layer wherein said interlayer dielectric comprises silicon, oxygen, fluorine and nitrogen and wherein said interlayer dielectric comprises between 0.010-0.10 atomic percent nitrogen.

4. The integrated circuit of claim 3 wherein said interlayer dielectric comprises between 3-10 atomic percent fluorine.

5. A method of forming a integrated circuit, comprising the steps of:
forming a patterned metal layer above a substrate;
forming a silicon oxide nitride fluorine film having between about 0.010.10 atomic percent nitrogen over said pattern metal layer.

6. The method of claim 5 wherein said silicon oxide nitride fluorine film has between about 3-10 atomic percent fluorine.

7. A method of forming a fluorine—silicon—oxide nitrogen film comprising:
providing a silicon fluorine compound into a deposition chamber;
providing an oxygen containing gas into said deposition chamber;
providing a nitrogen containing gas into said deposition chamber; and
forming a fluorine—silicon—oxide film from said silicon fluorine compound, said oxygen containing gas, and said nitrogen containing gas.

8. The method of claim 7 wherein said silicon fluorine compound is SiF₄.

9. The method of claim 7 wherein said oxygen containing gas is O₂.

10. The method of claim 7 wherein said nitrogen containing gas is N₂.

11. The method of claim 7 wherein said deposition chamber is a high density plasma chamber.

12. The method of claim 7 wherein said substrate is heated to a temperature between 300-450° C. while forming said fluorine—silicon—oxide film.

13. The method of claim 7 wherein said deposition chamber is maintained at a pressure between 1.0-10 mtorr while forming said fluorine—silicon—oxide film.

14. The method of claim 7 wherein said silicon fluorine compound has a partial pressure of between 0.1-11.0 mtorr in said deposition chamber during said formation of said fluorine—silicon—oxide film.

15. The method of claim 7 wherein said nitrogen containing gas has a partial pressure of between 0.1 to 0.2 mtorr during the formation of said fluorine doped silicon oxide film.

16. The method of claim 2 wherein said partial pressure of said oxygen containing gas to said partial pressure of said nitrogen containing gas is at least 5:1.

17. The method of claim 7 wherein said fluorine doped silicon oxide film comprises between 0.010-0.10 atomic percent nitrogen.

18. The method of claim 7 wherein said fluorine—silicon—oxide film comprises between 3-10 atomic percent fluorine.

19. A method of forming a fluorine—silicon—oxide film over a patterned metal layer formed on a substrate, comprising:
providing SiF₄ into a deposition chamber containing said substrate;
providing O₂ into said deposition chamber;
providing N₂ into said deposition chamber; and
forming said fluorine—silicon—oxide film onto said pattern metal layer by decomposing said SiF₄, said O₂ and said N₂.

20. The method of claim 19 further comprising the step of heating said substrate to a deposition between 300-450° C. while forming said silicon—oxide—flourine film.

21. The method of claim 19 further comprising the step of generating a pressure in said deposition chamber between 1.0-10 mtorr while depositing said silicon—oxide—flourine film.

22. The method of claim 19 wherein at least 5 times more O₂ is provided into said chamber than N₂ while depositing said film.

23. The method of claim 19 further comprising providing Argon into said deposition chamber while depositing said film.

24. The method of claim 19 wherein no Argon is provided into said chamber while depositing said film.

25. The method of claim 19 further comprising heating said substrate from a first temperature to a deposition temperature while providing N₂ and O₂ and not SiF₄ into said chamber.

26. The method of claim 19 further comprising providing a silicon source gas into said deposition chamber in addition to said SiF₄.

27. The method of claim 26 wherein said silicon source gas is SiH₄.
